(19) United States
(12) Patent Application Publication
(10) Pub. No.: US 2008/0100343 A1
(43) Pub. Date: May 1, 2008

(54) Source Driver and Level Shifting Apparatus Thereof

(75) Inventor: Yu-Jui CHANG, Tainan County (TW)

Correspondence Address: LOWE HAUPTMAN HAM & BERNER, LLP, 1700 DIAGONAL ROAD, SUITE 300, ALEXANDRIA, VA, 22314, US

(73) Assignee: HIMAX TECHNOLOGIES LIMITED, Hsinhua (TW)

(21) Appl. No.: 11/555,492

(22) Filed: Nov. 1, 2006

(51) Int. Cl. H03K 19/0175

(52) U.S. Cl. 326/81

(57) ABSTRACT

The present invention discloses a source driver and a level shifting apparatus thereof. The level shifting apparatus comprises a level shifter and an asynchronous dynamic control circuit. The level shifter has a first switch and connected to a high power supply voltage source via the first switch, wherein the level shifter shifts a level of an input signal and outputs an output signal if enabled. The asynchronous dynamic control circuit sends an enabling signal for temporarily turning on the first switch to enable the level shifter.

### FIELD OF THE INVENTION

The present invention relates to a level shifting apparatus for use in a source driver, and more particularly, to a level shifting apparatus having an asynchronous dynamic control circuit.

### BACKGROUND OF THE INVENTION

FIG. 1 illustrates a diagram of a source driver used in a LCD (Liquid Crystal Display) device. The source driver shown in FIG. 1 comprises a shift register 102, a latch buffer 104, a level shifter 106 and a digital-to-analog converter (DAC) 108. The latch buffer 104 stores and outputs digital data signals by the control of the shift register 102. The level shifter 106 shifts voltage levels of the digital data signals to predetermined voltage levels. The digital-to-analog converter (DAC) 108 generates a driving voltage according to the outputted signals from the level shifter 106.

FIG. 2 illustrates a diagram of a conventional level shifter. As shown in FIG. 2, the level shifter comprises a first transistor 202, a second transistor 204, a third transistor 206, a fourth transistor 208, and a fifth transistor 210. The first transistor 202, the fourth transistor 208 and the fifth transistor 210 are P type transistors while the second transistor 204 and the third transistor 206 are N type transistors. The first transistor 202 has a source connected to a high power supply voltage source VDDA, and a gate connected to a low power supply voltage source VSSA, and thus makes the first transistor 202 always turned on.

The second transistor 204 has a source connected to the low power supply voltage source VSSA, a drain connected to an inverted output node 214, and a gate connected to an input node IN1 for receiving the digital data signal. The third transistor 206 has a source connected to the low power supply voltage source VSSA, a drain connected to an output node 212, and a gate connected to an inverted input node IN2 for receiving a voltage corresponding to the opposite logic state of the digital data signal. The fourth transistor 208 has a drain connected to the drain of the second transistor 204 at the inverted output node 214, a gate connected to the drain of the third transistor 206 at the output node 212, and a source connected to the drain of the first transistor 202. The fifth transistor 210 has a drain connected to the output node 212, a gate connected to the inverted output node 214, and a source connected to the drain of the first transistor 202.

Since the first transistor 202 is always turned on, there is always current flowing through the level shifter and thus results in power consumption any time.

### SUMMARY OF THE INVENTION

Therefore, one objective of the present invention is to provide a level shifting apparatus having an asynchronous dynamic control circuit to enable a level shifter.

Another objective of the present invention is to provide a source driver having a level shifting apparatus with an asynchronous dynamic control circuit.

Still another objective of the present invention is to provide a level shifting apparatus with an asynchronous dynamic control circuit in which the power consumption is reduced.

Still another objective of the present invention is to provide a level shifting apparatus with an asynchronous dynamic control circuit in which the noise shown on the display during power off is prevented.

According to the aforementioned objectives, the present invention provides a level shifting apparatus comprising a level shifter and an asynchronous dynamic control circuit. The level shifter has a first switch and connected to a high power supply voltage source via the first switch, wherein the level shifter shifts a level of an input signal and outputs an output signal if enabled. The asynchronous dynamic control circuit sends an enabling signal for temporarily turning on the first switch to enable the level shifter.

According to the preferred embodiment of the present invention, the asynchronous dynamic control circuit comprises a delay circuit so as to generate the enabling signal. The asynchronous dynamic control circuit comprises a first inverter, a delay circuit, and a NAND gate. The first inverter receives a first signal in associate with the input signal of the level shifter and outputs an inverted first signal. The delay circuit receives the inverted first signal and outputs a delay signal. The NAND gate receives the first signal and the delay signal for generating a pulse signal. The enabling signal is generated based on the pulse signal. The asynchronous dynamic control circuit further comprises a second inverter, a voltage-shifting circuit and a third inverter. The second inverter inverts the pulse signal sent from the NAND gate. The voltage-shifting circuit raises the level of the inverted pulse signal for outputting a high-voltage pulse signal. The third inverter inverts the high-voltage pulse signal to generate the enabling signal sent to the level shifter.

According to the preferred embodiment of the present invention, the asynchronous dynamic control circuit comprises a first inverter, a delay circuit, a voltage-shifting circuit, a NAND gate and a buffer. The first inverter receives a first signal in associate with the input signal of the level shifter and outputs an inverted first signal. The delay circuit receives the inverted first signal and outputs a delay signal. The voltage-shifting circuit raises the levels of the delay signal and the first signal for outputting a high-voltage delay signal and a high-voltage first signal. The NAND gate receives the high-voltage first signal and the high-voltage delay signal for generating a pulse signal. The buffer generates the enabling signal based on the pulse signal. The buffer further comprises two inverters.

According to the preferred embodiment of the present invention, the level shifter further comprises a second transistor, a third transistor, a fourth transistor, and a fifth transistor. The second transistor has a source connected to a low power supply voltage source, a drain connected to an inverted output node, and a gate receiving the input signal. The third transistor has a source connected to the low power supply voltage source, a drain connected to an output node, and a gate receiving a voltage corresponding to the opposite logic state of the input signal. The fourth transistor has a drain connected to the drain of the second transistor at the inverted output node, a gate connected to the drain of the third transistor at the output node, and a source connected to the first switch. The fifth transistor has a drain connected to the output node, a gate connected to the inverted output node, and a source connected to the first switch. The second transistor and the third transistor are N type transistors while the fourth transistor and the fifth transistor are P type transistors.

According to another objective, the present invention provides a source driver comprising a latch buffer, a level shifting apparatus and a digital/analog converter. The latch buffer outputs an input signal. The level shifting apparatus comprises a level shifter and an asynchronous dynamic control circuit. The level shifter has a first switch and connected to a high power supply voltage source via the first switch, wherein the level shifter shifts a level of the input signal and outputs an output signal if enabled. The asynchronous dynamic control circuit sends an enabling signal for temporarily turning on the first switch to enable the level shifter. The digital/analog converter receives the output signal for outputting a driving voltage.

### BRIEF DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 illustrates a diagram of a source driver used in a LCD device;

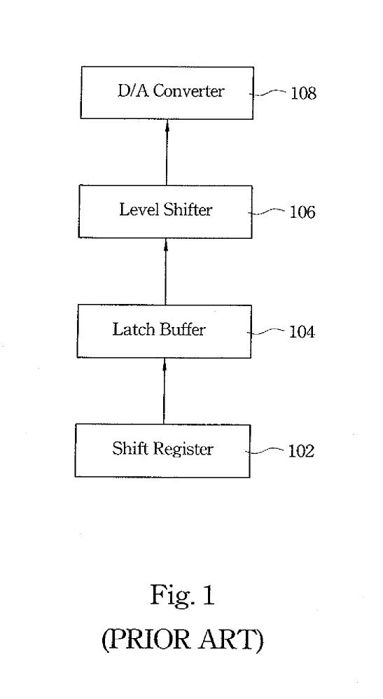

FIG. 2 illustrates a diagram of a conventional level shifter;

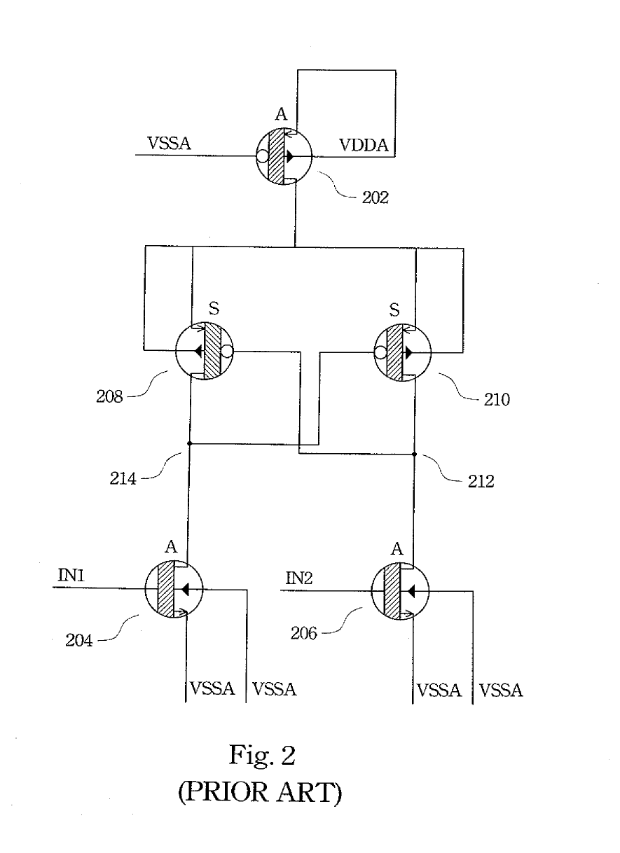

FIG. 3 illustrates a diagram of a source driver used in a LCD device according to the preferred embodiment of the present invention;

FIG. 4 illustrates a diagram of the level shifting apparatus according to the preferred embodiment of the present invention;

FIG. 5 illustrates a diagram of the asynchronous dynamic control circuit according to the preferred embodiment of the present invention; and

FIG. 6 illustrates another diagram of the asynchronous dynamic control circuit according to the preferred embodiment of the present invention.

### DETAILED DESCRIPTION OF THE PREFERRED EMBODIMENT

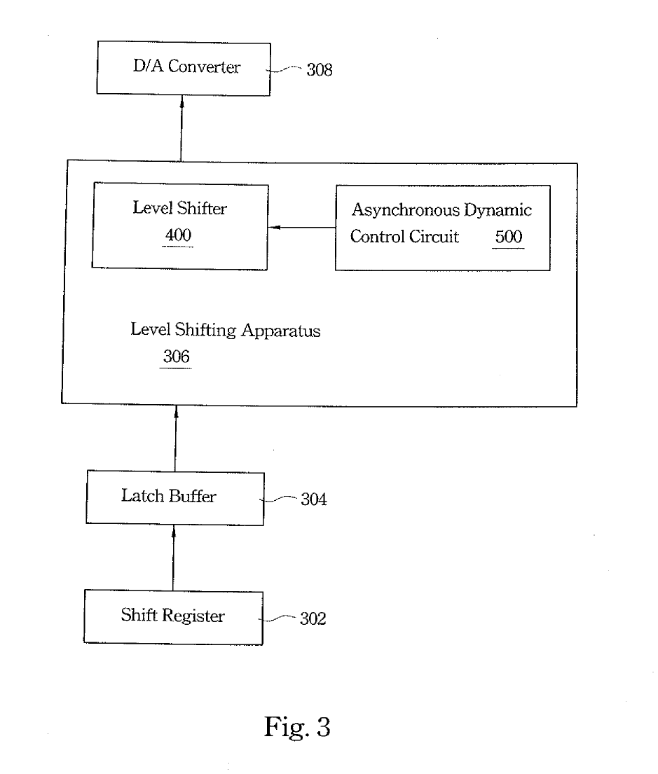

In order to make the illustration of the present invention more explicit and complete, the following description is stated with reference to FIGS. 3 through 6.

Reference is made to FIG. 3 illustrating a diagram of a source driver used in a LCD device according to the preferred embodiment of the present invention. The source driver shown in FIG. 3 comprises a shift register 302, a latch buffer 304, a level shifting apparatus 306 and a digital-to-analog converter (DAC) 308. The latch buffer 304 stores and outputs an input signal according to the shift register 302. The level shifting apparatus 306 shifts a level of the input signal and outputs an output signal. The digital-to-analog converter (DAC) 308 receives the output signal for outputting a driving voltage.

The level shifting apparatus 306 comprises a level shifter 400 and an asynchronous dynamic control circuit 500. The level shifter 400 has a first switch and connected to a high power supply voltage source VDDA via the first switch, wherein the level shifter shifts the level of the input signal and outputs the output signal if enabled. The asynchronous dynamic control circuit 500 sends an enabling signal for temporarily turning on the first switch to enable the level shifter 400. The detail of the level shifting apparatus will be described as follows.

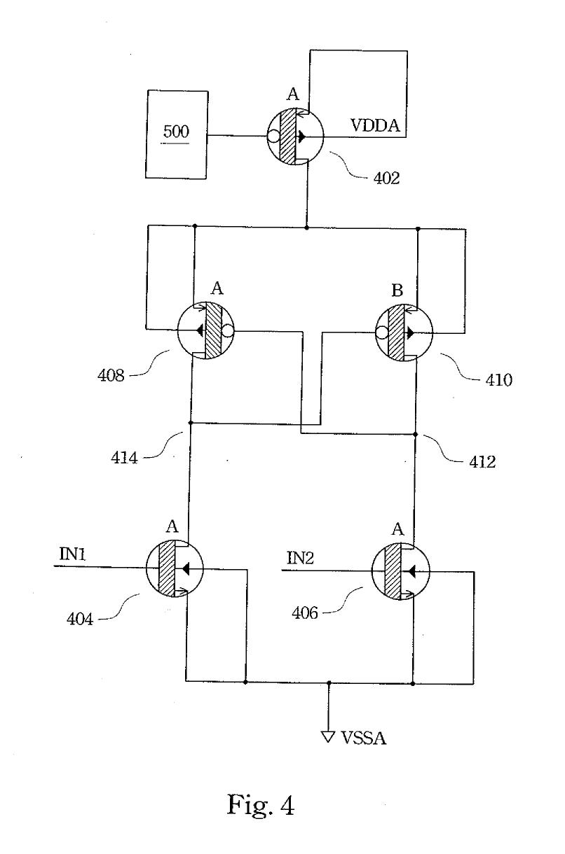

Reference is made to FIG. 4 illustrating a diagram of the level shifting apparatus according to the preferred embodiment of the present invention. As shown in FIG. 4, the level shifting apparatus 306 comprises a level shifter 400 and the asynchronous dynamic control circuit 500. The level shifter comprises a first transistor 402, a second transistor 404, a third transistor 406, a fourth transistor 408, and a fifth transistor 410. The first transistor 402, the fourth transistor 408 and the fifth transistor 410 are P type transistors while the second transistor 404 and the third transistor 406 are N type transistors. The first transistor 402 has a source connected to a high power supply voltage source VDDA, and a gate connected to the asynchronous dynamic control circuit 500.

The second transistor 404 has a source connected to the low power supply voltage source VSSA, a drain connected to an inverted output node 414, and a gate connected to an input node IN1 for receiving the input signal. The third transistor 406 has a source connected to the low power supply voltage source VSSA, a drain connected to an output node 412, and a gate connected to an inverted input node IN2 for receiving a voltage corresponding to the opposite logic state of the input signal. The fourth transistor 408 has a drain connected to the drain of the second transistor 404 at the inverted output node 414, a gate connected to the drain of the third transistor 406 at the output node 412, and a source connected to the drain of the first transistor 402. The fifth transistor 410 has a drain connected to the output node 412, a gate connected to the inverted output node 414, and a source connected to the drain of the first transistor 402.

The asynchronous dynamic control circuit 500 sends an enabling signal to temporarily turn on the first transistor 402, functioning as a switch, to enable the level shifter. When the level shifter 400 is enabled and when the input signal has a state as logic high, the second transistor 404 is turned on, and the fifth transistor 410 is also then turned on. Then, the output signal is outputted from the output nodes 412 and 414. On the contrary, when the level shifter is enabled and when the input signal has a state as logic low, the third transistor 406 that receiving a voltage corresponding to the opposite logic state of the input signal receives a state as logic high, so the third transistor 406 is turned on, and the fourth transistor 408 is also then turned on. Then, the output signal is outputted from the output nodes 412 and 414. When the level shifter is not enabled by the asynchronous dynamic control circuit 500, the level shifter does not work.

Hence, a feature of the preferred embodiment is that the asynchronous dynamic control circuit temporarily turns on the level shifter when a new input signal is inputted to the level shifter, and thus the power consumption is reduced. Furthermore, the asynchronous dynamic control circuit can prevent the display from showing the noise during the power being turned off.

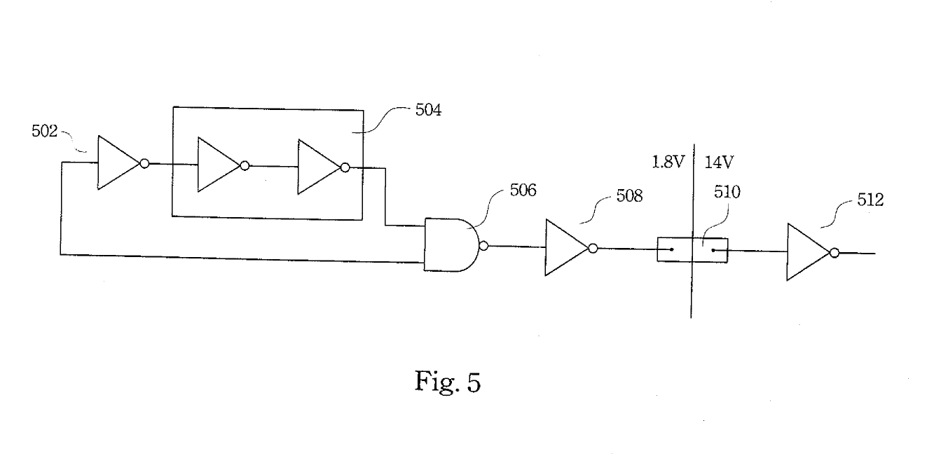

Reference is made to FIG. 5 illustrating a diagram of the asynchronous dynamic control circuit according to the preferred embodiment of the present invention. The asynchronous dynamic control circuit shown in FIG. 5 comprises a first inverter 502, a delay circuit 504, a NAND gate 506, a second inverter 508, a voltage-shifting circuit 510 and a third inverter 512. The delay circuit 504 may comprises even number of inverters. The first inverter 502 receives a first signal from the latch buffer 304 in associate with the input signal of the level shifter and outputs an inverted first signal. The delay circuit 504 receives the inverted first signal and outputs a delay signal. The NAND gate 506 receives the first signal and the delay signal for generating a pulse signal. The duration time of the pulse signal is determined based on the delay circuit 504 and the first inverter 502. The second inverter 508 inverts the pulse signal sent from the NAND gate 506. The voltage-shifting circuit 510 raises the level of the inverted pulse signal for outputting a high-voltage pulse signal. The third inverter 512 inverts the high-voltage pulse signal to generate the enabling signal sent to the level shifter.

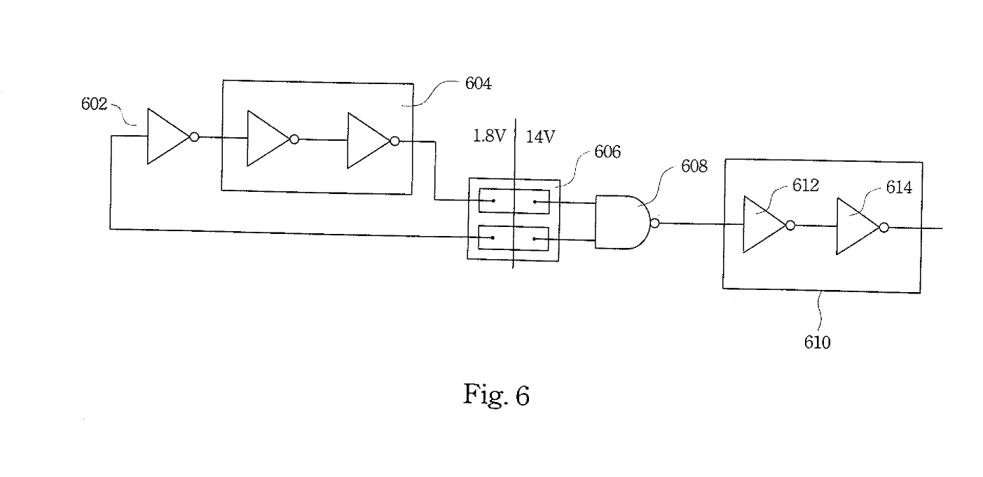

Reference is made to FIG. 6 illustrating another diagram of the asynchronous dynamic control circuit according to the preferred embodiment of the present invention. The asynchronous dynamic control circuit shown in FIG. 6 comprises a first inverter 602, a delay circuit 604, a voltage-shifting circuit 606, a NAND gate 608 and a buffer 610. The delay circuit 604 may comprises even number of inverters. The buffer 610 further comprises two inverters (612, 614). The first inverter 602 receives a first signal in associate with the input signal of the level shifter and outputs an inverted first signal. The delay circuit 604 receives the inverted first signal and outputs a delay signal. The voltage-shifting circuit 606 raises the levels of the delay signal and the first signal for outputting a high-voltage delay signal and a high-voltage first signal. The NAND gate 608 receives the high-voltage first signal and the high-voltage delay signal for generating a pulse signal. The buffer 610 generates the enabling signal based on the pulse signal.

According to the aforementioned description, one advantage of the preferred embodiment is that the power consumption in the level shifting apparatus of the present invention is reduced.

According to the aforementioned description, another advantage of the preferred embodiment is that the level shifting apparatus has an asynchronous dynamic control circuit, so the noise shown on the display during power off can be prevented.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A level shifting apparatus comprising:
a level shifter having a first switch and connected to a high power supply voltage source via the first switch, wherein the level shifter shifts a level of an input signal and outputs an output signal if enabled; and
an asynchronous dynamic control circuit, sending an enabling signal for temporarily turning on the first switch to enable the level shifter.

2. The apparatus as claimed in claim 1, wherein the asynchronous dynamic control circuit comprises a delay circuit so as to generate the enabling signal.

3. The apparatus as claimed in claim 1, wherein the asynchronous dynamic control circuit comprises:
a first inverter for receiving a first signal in associate with the input signal of the level shifter and outputting an inverted first signal;
a delay circuit receiving the inverted first signal and outputting a delay signal; and
a NAND gate receiving the first signal and the delay signal for generating a pulse signal;
wherein the enabling signal is generated based on the pulse signal.

4. The apparatus as claimed in claim 3, wherein the asynchronous dynamic control circuit further comprises:
a second inverter inverting the pulse signal sent from the NAND gate;
a voltage-shifting circuit raising the level of the inverted pulse signal for outputting a high-voltage pulse signal; and
a third inverter inverting the high-voltage pulse signal to generate the enabling signal.

5. The apparatus as claimed in claim 1, wherein the asynchronous dynamic control circuit comprises:
a first inverter for receiving a first signal in associate with the input signal of the level shifter and outputting an inverted first signal;
a delay circuit receiving the inverted first signal and outputting a delay signal;
a voltage-shifting circuit raising the levels of the delay signal and the first signal for outputting a high-voltage delay signal and a high-voltage first signal;
a NAND gate receiving the high-voltage first signal and the high-voltage delay signal for generating a pulse signal; and
a buffer for generating the enabling signal based on the pulse signal.

6. The apparatus as claimed in claim 5, wherein the buffer comprises two inverters.

7. The apparatus as claimed in claim 1, wherein the level shifter further comprises:
a second transistor having a source connected to a low power supply voltage source, a drain connected to an inverted output node, and a gate receiving the input signal;
a third transistor having a source connected to the low power supply voltage source, a drain connected to an output node, and a gate receiving a voltage corresponding to the opposite logic state of the input signal;
a fourth transistor having a drain connected to the drain of the second transistor at the inverted output node, a gate connected to the drain of the third transistor at the output node, and a source connected to the first switch; and
a fifth transistor having a drain connected to the output node, a gate connected to the inverted output node, and a source connected to the first switch.

8. The apparatus as claimed in claim 7, wherein the second transistor and the third transistor are N type transistors while the fourth transistor and the fifth transistor are P type transistors.

9. A source driver comprising:
a latch buffer for outputting an input signal;
a level shifting apparatus comprising:
a level shifter having a first switch and connected to a high power supply voltage source via the first switch, wherein the level shifter shifts a level of the input signal and outputs an output signal if enabled; and
an asynchronous dynamic control circuit, sending an enabling signal for temporarily turning on the first switch to enable the level shifter; and
a digital/analog converter receiving the output signal for outputting a driving voltage.

10. The source driver as claimed in claim 9, wherein the asynchronous dynamic control circuit comprises a delay circuit so as to generate the enabling signal.

11. The source driver as claimed in claim 9, wherein the asynchronous dynamic control circuit comprises:
a first inverter for receiving a first signal in associate with the input signal of the level shifter and outputting an inverted first signal;
a delay circuit receiving the inverted first signal and outputting a delay signal; and
a NAND gate receiving the first signal and the delay signal for generating a pulse signal;
wherein the enabling signal is generated based on the pulse signal.

12. The source driver as claimed in claim 11, wherein the asynchronous dynamic control circuit further comprises:
a second inverter inverting the pulse signal sent from the NAND gate;
a voltage-shifting circuit raising the level of the inverted pulse signal for outputting a high-voltage pulse signal; and
a third inverter inverting the high-voltage pulse signal to generate the enabling signal.

13. The source driver as claimed in claim 9, wherein the asynchronous dynamic control circuit comprises:
a first inverter for receiving a first signal in associate with the input signal of the level shifter and outputting an inverted first signal;
a delay circuit receiving the inverted first signal and outputting a delay signal;
a voltage-shifting circuit raising the levels of the delay signal and the first signal for outputting a high-voltage delay signal and a high-voltage first signal;
a NAND gate receiving the high-voltage first signal and the high-voltage delay signal for generating a pulse signal; and
a buffer for generating the enabling signal based on the pulse signal.

14. The source driver as claimed in claim 13, wherein the buffer comprises two inverters.

15. The source driver as claimed in claim 9, wherein the level shifter further comprises:
a second transistor having a source connected to a low power supply voltage source, a drain connected to an inverted output node, and a gate receiving the input signal;
a third transistor having a source connected to the low power supply voltage source, a drain connected to an output node, and a gate receiving a voltage corresponding to the opposite logic state of the input signal;
a fourth transistor having a drain connected to the drain of the second transistor at the inverted output node, a gate connected to the drain of the third transistor at the output node, and a source connected to the first switch; and
a fifth transistor having a drain connected to the output node, a gate connected to the inverted output node, and a source connected to the first switch.

16. The source driver as claimed in claim 15, wherein the second transistor and the third transistor are N type transistors while the fourth transistor and the fifth transistor are P type transistors.
